(19) United States
(12) Patent Application Publication
(10) Pub. No.: US 2008/0230839 A1
(43) Pub. Date: Sep. 25, 2008

(54) Method of producing a semiconductor structure

(76) Inventors: Joern Regul, Egmating (DE); Joerg Radecker, Dresden (DE); Olaf Storbeck, Dresden (DE); Kristin Schupke, Dresden (DE); Tobias Mono, Dresden (DE)

Correspondence Address: SLATER & MATSIL, L.L.P., 17950 PRESTON ROAD, SUITE 1000, DALLAS, TX, 75252, US

(21) Appl. No.: 11/728,196

(22) Filed: Mar. 23, 2007

(51) Int. Cl. H01L 29/76; H01L 21/44; H01L 29/94

(52) U.S. Cl. 257/368; 257/410; 438/653; 257/E29.229

(57) ABSTRACT

The invention is related to a method of producing a semiconductor structure comprising the steps of: fabricating a gate stack structure and oxidizing at least a portion of the gate stack structure's sidewalls, wherein the step of oxidizing is carried out at a temperature below 500° C. using a process gas which comprises oxygen radicals.

### TECHNICAL FIELD

The invention is related to a method of producing a semiconductor structure. More particularly, the invention is directed to a method wherein a gate contact is fabricated and thereafter at least partly oxidized.

### BACKGROUND

The oxidation step may cause significant problems to gate contact stacks that include a plurality of layers. For example, diffusion barrier layers included inside the gate stack may be altered or destroyed during the oxidation.

### SUMMARY OF THE INVENTION

The invention relates to a method for producing a semiconductor structure comprising the steps of fabricating a gate contact and oxidizing at least a portion of the contact's sidewalls, wherein the step of oxidizing is carried out at a temperature below 500° C. using a process gas which comprises oxygen radicals.

The method according to the invention uses oxygen radicals for oxidizing the contact's sidewalls. The oxygen radicals allow for oxidation at much lower temperatures than those required for thermal oxidation. As a consequence, the integrity of the layers and their chemical structure are maintained.

An embodiment of the invention further provides a gate contact stack comprising at least an upper conductive layer, a lower conductive layer and a diffusion barrier layer therebetween, wherein the edge of the lower conductive layer is oxidized.

Furthermore, a further embodiment of the invention provides a semiconductor device comprising an upper conductive layer, a lower conductive layer and a diffusion barrier layer therebetween, wherein the edge of the lower conductive layer is oxidized.

### DESCRIPTION OF THE DRAWINGS

In order that the manner in which the above-recited and other advantages of the invention are obtained will be readily understood, a more particular description of the invention briefly described above will be rendered by reference to specific embodiments thereof which are illustrated in the appended drawings. Understanding that these drawings depict only typical embodiments of the invention and are not therefore to be considered to be limiting of its scope, the invention will be described and explained with additional specificity and detail through the use of the accompanying drawings in which

FIGS. 1-7 show a first embodiment of the invention wherein a cap liner protects an upper conductive layer and a diffusion barrier layer during a low temperature radical oxidation; and

FIG. 8-13 show a second embodiment of the invention wherein all edges of the gate stack layers are subjected to a low temperature radical oxidation.

### DETAILED DESCRIPTION OF ILLUSTRATIVE EMBODIMENTS

The preferred embodiment of the present invention will be best understood by reference to the drawings, wherein like parts are designated by like numerals throughout.

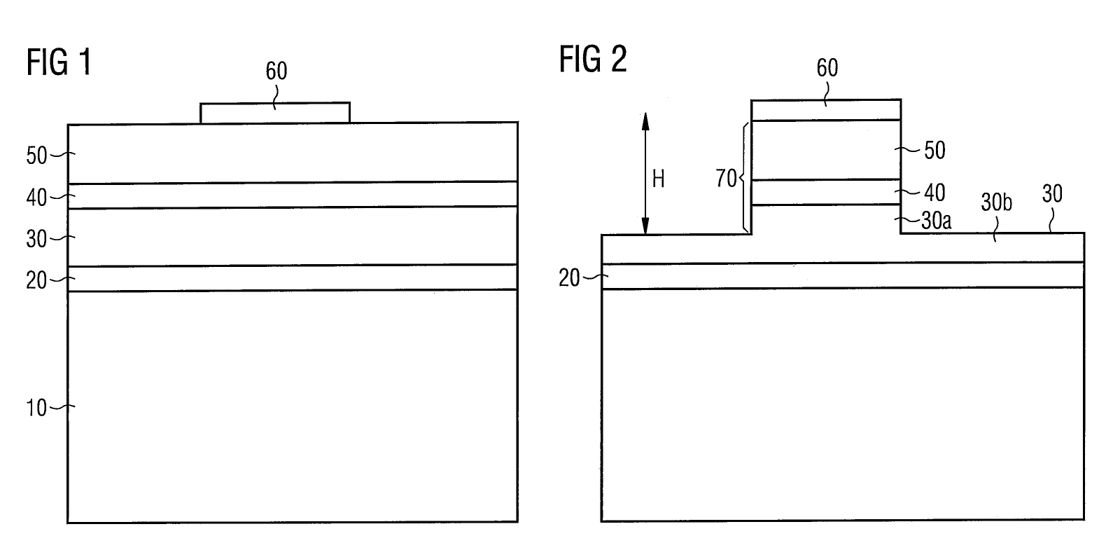

It will be readily understood that the process steps of the present invention, as generally described and illustrated in the figures herein, could vary in a wide range of different process steps. Thus, the following more detailed description of the exemplary embodiments of the present invention, as represented in FIGS. 1-13 is not intended to limit the scope of the invention, as claimed, but is merely representative of a presently preferred embodiment of the invention.

An aspect of the present invention is to provide a method for fabricating a semiconductor device. As exemplary embodiment of the invention a fabrication of a gate stack for a field effect transistor is described hereinafter.

FIGS. 1-7 show a first embodiment of the invention. In a first process step, a gate oxide layer 20 is grown on a silicon substrate 10, e.g., by thermal oxidation. Thereafter, a plurality of gate stack layers 30, 40 and 50 are deposited on the gate oxide layer 20. A lower conductive layer 30 may consist of or contain polysilicon material. An upper conductive layer 50 may consist of or contain tungsten. The upper conductive layer 50 and the lower conductive layer 30 are separated by a diffusion barrier layer 40 which prevents tungsten atoms from diffusing into the polysilicon layer 30 or silicon to penetrate into the tungsten layer. The diffusion barrier layer 40 may consist of or contain TiN.

FIG. 1 also depicts a mask 60 that may be fabricated during a lithography step.

In FIG. 2, the resulting structure is shown after etching the upper conductive layer 50, the diffusion barrier layer 40 and the lower conductive layer 30 to a predetermined depth H. It can be seen, that the lower conductive layer 30 now comprises a lower unetched portion 30b and an upper etched portion 30a. The resulting gate contact stack is designated by reference numeral 70.

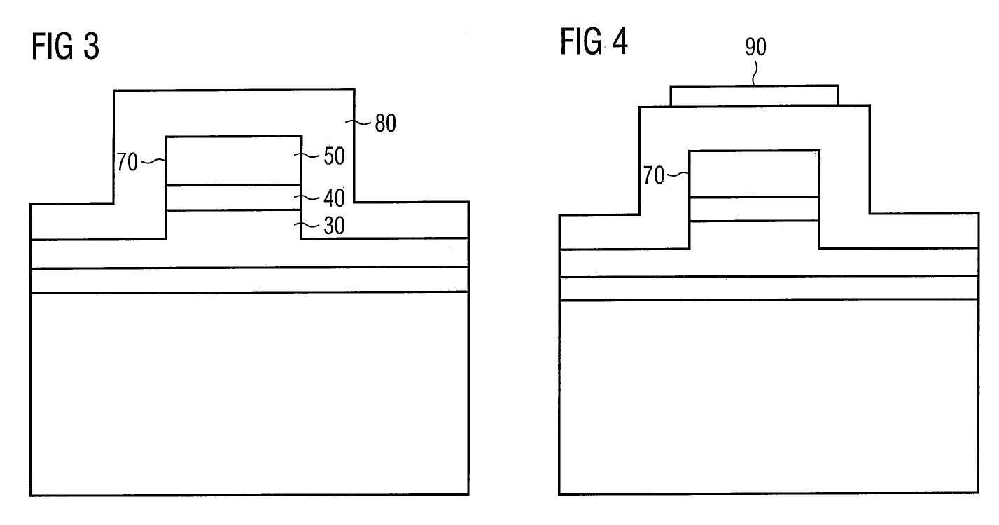

After etching the gate stack layers 30, 40 and 50 a cap layer 80 is deposited thereon as shown in FIG. 3. The cap layer 80 may consist of any insulating material such as silicon oxide or silicon nitride.

Then a mask 90 is fabricated during a further lithography step. As can be seen in FIG. 4, the mask 90 is aligned to contact stack 70.

Afterwards, the cap layer 80 and the gate contact stack 70 are etched down to the gate oxide layer 20. During this etch step, the polysilicon material of the lower conductive layer 30 is removed from the gate oxide layer 20 outside the gate stack area in order to provide a clean oxide surface for further processing.

FIG. 5 shows the etched gate contact stack 70. It can be seen that a vertical cap portion 80a of the cap 80 covers the edge 50a of the upper conductive layer 50 and the edge 40a of the diffusion barrier layer 40. The vertical cap portion 80a further covers the edge 30a′ of the upper portion 30a of the polysilicon layer 30.

Thereafter, the gate contact stack 70 is subjected to a “low temperature radical oxidation.” The term “low temperature radical oxidation” refers to an oxidation step wherein oxygen radicals are applied at a relatively low temperature below 500° C. Preferably, the oxygen radicals are produced in a plasma, e.g., a remote plasma. The material flow of the radicals may be undirected or directed versus the substrate 20. The following process parameters have been found to be advantageous:

Pressure: <10 mTorr

RF power: 500-9000 W

Gases: O₂, He, H₂, Ar (50-1000 sccm)

Temperature: 300° C.-400° C.

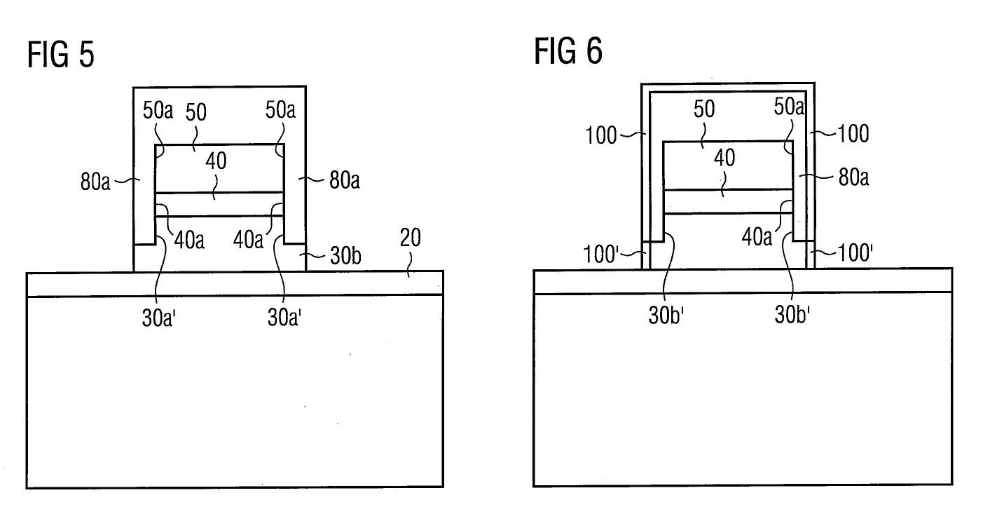

As can be seen in FIG. 6, the vertical cap portion 80a protects the edge 50a of the upper conductive layer 50 and the edge 40a of the diffusion barrier layer 40 such that these layers are not oxidized. The resulting layers on top of the cap 80 and on top of the edge 30b′ of the lower portion 30b of the lower conductive layer 30 are marked with reference numerals 100 and 100′ in FIG. 6. Layers 100 and 100′ may consist of different materials and may have a different thickness.

During this oxidation step the gate oxide layer 20 is also cleaned. For example, any polysilicon residuals which have not been successfully removed during the etch step as explained with regard to FIG. 6, are oxidized to silicon oxide and now belong to the SiO₂ material of the gate oxide layer 20 thus preventing shorts between gate stack structures otherwise caused by these polysilicon residuals.

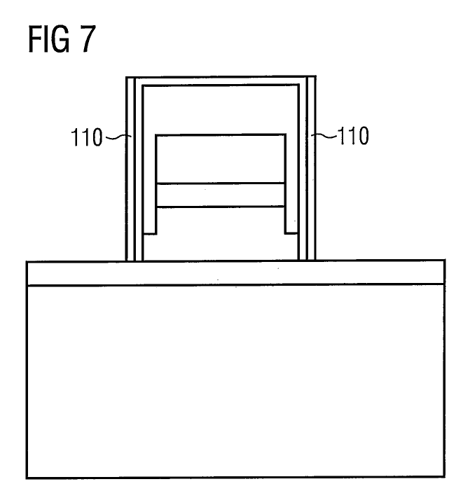

After completing the low temperature radical oxidation, spacers 110 may be deposited on the gate stack's sidewalls (see FIG. 7). Such spacers 110 may consist of silicon oxide such as TEOS oxide or of silicon nitride. Alternatively, layer 80 may be removed before applying the spacers 110.

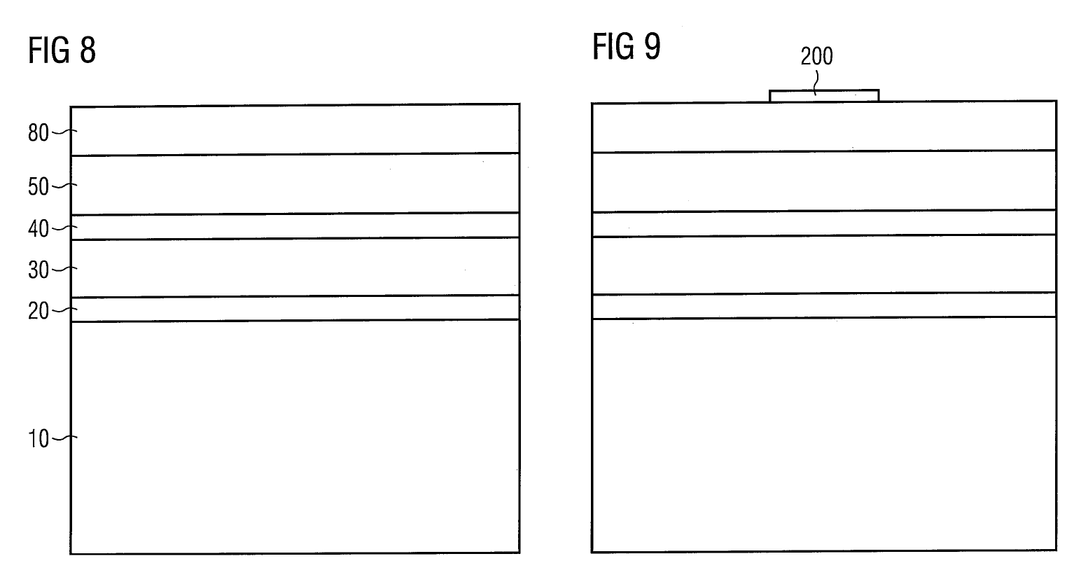

A second embodiment of the invention will now be explained referring to FIGS. 8-13.

FIG. 8 shows a substrate 10 after forming a gate oxide layer 20 and depositing a lower conductive layer 30, a diffusion barrier layer 40, an upper conductive layer 50 and a cap layer 80. Layers 30, 40, 50 and 80 may consist of polysilicon, TiN, tungsten and silicon nitride, respectively.

On top of the cap layer 80 a mask 200 is fabricated during a photolithography step. This is depicted in FIG. 9.

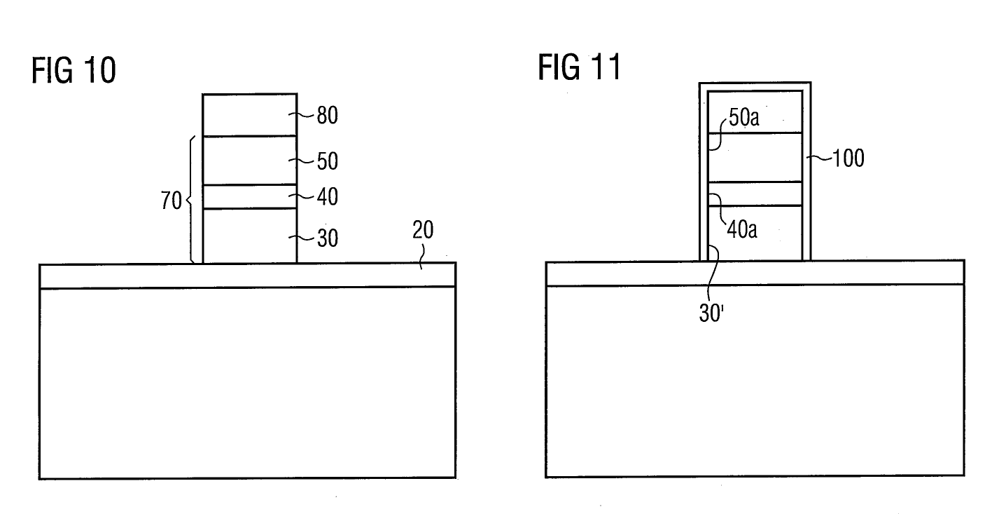

The resulting structure is subjected to an anisotropic etch step wherein a gate contact stack 70 is formed. All gate stack layers 30, 40 and 50 are removed outside the stack area (see FIG. 10).

Thereafter, the gate contact stack 70 is subjected to a low temperature radical oxidation. Again, the following process parameters have been found to be advantageous:

Pressure: <10 mTorr

RF power: 500-9000 W

Gases: O2, He, H2, Ar (50-1000 sccm)

Temperature: 300° C.-400° C.

As can be seen in FIG. 11, each layer edge 50a, 40a and 30′ is oxidized during the oxidation step. Depending on the specific process condition of the oxidation, the upper conductive layer 50 might not be oxidized. The buried TiN diffusion barrier layer 40 is not destroyed during the oxidation step because appropriate material for the diffusion barrier, like for example TiN, can be chemically stable up to these temperatures. The oxide layer is designated by reference numeral 100 in FIG. 11.

During the oxidation step the gate oxide layer 20 is also cleaned. For example, any polysilicon residuals which have not been successfully removed during the etch step shown FIG. 10, are oxidized to silicon oxide and now belong to the SiO₂ material of the gate oxide layer 20.

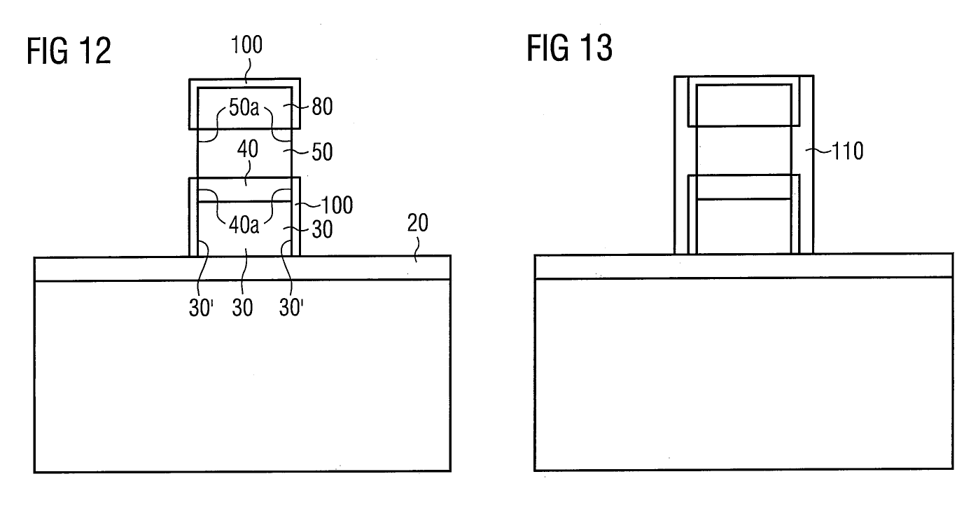

Thereafter, the oxidized gate stack 70 is preferably wet chemically etched. Etch chemicals are used which selectively etch the tungsten oxide at the edge 50a of the tungsten layer 50 and which keep the other edges 40a and 30′ of layers 40 and 30 unetched. For example, etch chemicals comprising NH₄0H provide a good selectivity to remove the tungsten oxide, only. This is shown in FIG. 12. In case of not having oxidized the sidewall of the upper conductive layer 50, the chemistry of the following clean step might be altered due to the fact that the requirement to remove the oxide of the upper conductive layer 50 is obsolete in this case.

For selectively removing tungsten oxide, the following etch chemicals and process parameters provide good results:

Temperature: 20° C.-50° C.

etch chemical: NH₄OH and H₂O: 1:500-1:10

After removing the tungsten oxide, a spacer 110 is deposited on the gate stack's sidewalls. The complete gate stack structure is depicted in FIG. 13.

The removal of the tungsten oxide is particularly advantageous if the gate stack structure is subjected to subsequent high temperature process steps. Tungsten oxide's thermal stability is limited to about 600° C. Therefore, during subsequent processing, tungsten oxide may cause thermal stress inside the gate stack 70 which can destroy layers on top of the tungsten oxide when the gate stack is heated up to temperatures above 600° C. By removal of the tungsten oxide from the edge 50a of layer 50 thermal stress is significantly reduced.

What is claimed is:

1. Method of producing a semiconductor structure comprising the steps of:
fabricating a gate stack structure and
oxidizing at least a portion of the gate stack structure's sidewalls,
wherein the step of oxidizing is carried out at a temperature below 500° C. using a process gas which comprises oxygen radicals.

2. Method of claim 1, wherein
a plasma is generated to form the oxygen radicals.

3. Method of claim 2, wherein the gate stack structure comprises at least an upper conductive layer and a lower conductive layer.

4. Method of claim 3, wherein the gate stack structure comprises a diffusion barrier layer.

5. Method of claim 4, wherein the diffusion barrier layer comprises TiN.

6. Method of claim 4, wherein at least one of the conductive layers comprises tungsten.

7. Method of claim 6, wherein after oxidizing the gate stack's sidewalls tungsten oxide is removed from the edge of the tungsten containing layer.

8. Method of claim 7, wherein a spacer is deposited on the gate contact stack's sidewalls after removing the tungsten oxide.

9. Method of claim 4, wherein at least one of the layers comprises polysilicon.

10. Method of producing a semiconductor structure comprising the steps of:
fabricating a gate stack comprising at least a lower conductive layer, an upper conductive layer and a diffusion barrier layer therebetween; and
oxidizing at least a lower portion of the edge of the lower conductive layer,
wherein the step of oxidizing is carried out at a temperature below 500° C. using a process gas which comprises oxygen radicals.

11. Method of claim 10, wherein
a plasma is generated to form the oxygen radicals.

12. Method of claim 10, further comprising the step of:
forming an insulating cap on top of the gate contact stack,
wherein the cap covers at least the edge of the upper conductive layer, the edge of the diffusion barrier layer and the edge of an upper portion of the lower conductive layer.

13. Method of claim 12, wherein the sidewalls of the cap and the edge of a lower part of the lower conductive layer are exposed to the oxygen radicals during said oxidizing step.

14. Method of claim 13, wherein the diffusion barrier layer comprises TiN.

15. Method of claim 10, further comprising the steps of:
forming an insulating cap on top of the gate stack such that the edge of the upper conductive layer, the edge of the diffusion barrier layer and the edge of the lower conductive layer remain uncovered by said cap.

16. Method of claim 10, wherein said cap comprises silicon nitride.

17. Method of claim 15, wherein the edge of the upper conductive layer, the edge of the diffusion barrier layer and the edge of the lower conductive contact are oxidized during said oxidizing step.

18. Method of claim 17, wherein the diffusion barrier layer comprises TiN.

19. Method of claim 17, wherein the upper conductive layer comprises tungsten.

20. Method of claim 19, wherein, after oxidizing the gate stack, tungsten oxide is removed from the edge of the upper conductive layer.

21. Method of claim 19, wherein a spacer is provided on top of the gate stack's sidewalls after removing the tungsten oxide.

22. Method of claim 17, wherein the lower conductive layer comprises polysilicon.

23. Gate stack structure comprising
at least an upper conductive layer, a lower conductive layer and a diffusion barrier layer therebetween,
wherein the lower edge of the lower conductive layer is oxidized, and
wherein a spacer is provided which directly adjoins the edge of the upper conductive layer, the edge of the diffusion barrier layer and the upper portion of the edge of the lower conductive layer.

24. Gate stack structure of claim 23, wherein the upper conductive layer comprises tungsten.

25. Gate stack structure of claim 23, wherein the diffusion barrier layer comprises TiN.

26. Gate stack structure of claim 23, wherein the lower conductive layer comprises polysilicon.

27. Gate stack structure comprising
at least an upper conductive layer, a lower conductive layer and a diffusion barrier layer therebetween,
wherein the edge of the lower conductive layer and the edge of the diffusion barrier layer are oxidized, and
wherein a deposited spacer is provided which covers the non-oxidized edge of the upper conductive layer, the oxidized edge of the diffusion barrier layer and an upper portion of the oxidized edge of the lower conductive layer.

28. Integrated circuit comprising a gate stack structure comprising at least an upper conductive layer, a lower conductive layer and a diffusion barrier layer therebetween,
wherein the lower edge of the lower conductive layer is oxidized, and
wherein a spacer is provided which directly adjoins the edge of the upper conductive layer, the edge of the diffusion barrier layer and the upper portion of the edge of the lower conductive layer.

29. Integrated circuit comprising a gate stack structure
comprising at least an upper conductive layer, a lower conductive layer and a diffusion barrier layer therebetween,
wherein the edge of the lower conductive layer and the edge of the diffusion barrier layer are oxidized, and
wherein a deposited spacer is provided which directly adjoins the edge of the upper conductive layer, the oxidized edge of the diffusion barrier layer and the oxidized upper portion of the edge of the lower conductive layer.
